(19) United States
(12) Patent Application Publication
(10) Pub. No.: US 2026/0085441 A1
(43) Pub. Date: Mar. 26, 2026

(54) SUSTAINABLE COATINGS ON CONDUCTIVE PARTS SUCH AS A MAGNESIUM-BASED LAPTOP CHASSIS

(71) Applicant: Intel Corporation, Santa Clara, CA (US)

(72) Inventors: Prakash KURMA RAJU, Bangalore (IN); Prasanna PICHUMANI, Bangalore (IN); Akarsha KADADEVARAMATH, Bangalore (IN); Jeff KU, Taipei City (TW); Alonso RODRIGUEZ CHACON, La Guacima (CR)

(21) Appl. No.: 19/303,388

(22) Filed: Aug. 19, 2025

Related U.S. Application Data
(63) Continuation of application No. PCT/US2024/048249, filed on Sep. 25, 2024.

(51) Int. Cl. C25D 13/04; C09D 5/44; C25D 13/20; H01Q 1/22; H05K 5/02

(52) U.S. Cl. CPC C25D 13/04; C09D 5/4488; C25D 13/20; H01Q 1/2266; H05K 5/0243

(57) ABSTRACT

Disclosed herein is method for finishing a conductive part with a sustainable coating, where the part may be a magnesium-based chassis/housing for electronic equipment. The method includes depositing electrochemically a coating material onto the conductive surface of the component, placing a thin film over the coating material, and attaching the thin film onto the component by way of a vacuum transfer process. A graphite-based coating (e.g., graphene) may also be placed between the conductive surface and the thin film. The thin film may be decorative/cosmetic thin film to provide an attractive aesthetic.

### CROSS-REFERENCE TO RELATED APPLICATION(S)

This application claims priority to International Application No. PCT/US2024/048249 filed on Sep. 5, 2024, the contents of which is fully incorporated herein by reference.

### TECHNICAL FIELD

This application relates relate to coatings on conductive parts/components, and in particular on sustainable coatings that may be used on conductive parts such as a magnesium-based chassis/housing for electronic equipment or other types of parts.

### BACKGROUND

Thin and light laptops, especially high-performance laptops marketed for gaming applications, often use magnesium as a chassis due to its low weight and reasonable thermal conductivity. The magnesium also provides a sleek-looking design for the laptop cover. However, due to its poor corrosion resistance and material property, it must be coated, usually with a paint. This type of coating process, however, often compromises the recyclability of the part, and the resulting part/process may not be considered a sustainable product.

While the metallic laptop cover is desirable, such a cover makes it difficult to include a wireless antenna within the laptop. While the laptop industry is working to overcome hurdles in physics that would otherwise allow placement of an antenna on or within a metal chassis body, up till now, this has not been possible. As a result, laptop covers typically end up having a plastic chassis with a metallic-looking finish. Finding a suitable finish on the plastic chassis that provides for an attractive, thin, and light laptop has been problematic. Current industry practice for providing a seamless finish on a metal chassis is via a painting process, but this may result in an uneven coating on the laptop's cover.

### BRIEF DESCRIPTION OF FIGURES

In the drawings, like reference characters generally refer to the same parts throughout the different views. The drawings are not necessarily to scale, emphasis instead generally being placed upon illustrating the principles of the disclosure. In the following description, various aspects of the disclosure are described with reference to the following drawings, in which:

FIG. 1 shows an example flow chart for a conventional manufacturing process for producing a component, such as a laptop housing/cover, formed from a conductive material;

FIG. 2 illustrates an example flow chart for a conventional manufacturing process for producing a component, such as a laptop housing/cover, formed from a conductive material, where the painting has been replaced with a plastic with a chromate conversion, followed by a thin layer of aluminum that is then anodized;

FIG. 3 depicts an example flow chart for the disclosed process for producing a component, such as a laptop housing/cover, formed from a conductive material, where the process includes coating via cathode electrodeposition.

FIG. 4 shows an example flow chart for the disclosed process for producing a component, such as a laptop housing/cover, formed from a conductive material, where the process includes cathode electrodeposition and vacuum transfer molding;

FIG. 5 illustrates an example stack-up of a component, such as a laptop housing/cover, that has been prepared using the disclosed thin-film processing and that includes a graphite-based layer between the thin-film coating and the part's surface; and

FIG. 6 depicts a schematic flow diagram of a method for producing a metallic component/part with a thin film coating.

### DESCRIPTION

The following detailed description refers to the accompanying drawings that show, by way of illustration, exemplary details and features.

The word “exemplary” is used herein to mean “serving as an example, instance, or illustration”. Any aspect or design described herein as “exemplary” is not necessarily to be construed as preferred or advantageous over other aspects or designs.

Throughout the drawings, it should be noted that like reference numbers are used to depict the same or similar elements, features, and structures, unless otherwise noted.

The phrase “at least one” and “one or more” may be understood to include a numerical quantity greater than or equal to one (e.g., one, two, three, four, [ . . . ], etc., where “[ . . . ]” means that such a series may continue to any higher number). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. For instance, the phrase “a plurality” may be understood to include a numerical quantity greater than or equal to two (e.g., two, three, four, five, [ . . . ], etc., where “[ . . . ]” means that such a series may continue to any higher number).

The phrases “group (of)”, “set (of)”, “collection (of)”, “series (of)”, “sequence (of)”, “grouping (of)”, etc., in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

As noted above, conventional processes for creating housings (or other parts/components) for electronic equipment such as laptops, smartphones, wearables, etc. often struggle to provide a thin, light, sleek-looking housing that is sustainable and into which a wireless antenna may be attached/embedded. As discussed in more detail below, a new finishing technique is disclosed herein that improves sustainability, provides thermal efficiency, and helps to reduce emissions/waste across high-impact industries. In the new finishing technique disclosed below, the typical process of painting/anodizing the surface of the part is replaced with a cathodic-electrodeposition (or cathode electrodeposition or CED) and a water-based primer coat/vacuum film transfer on a metallic part (such as a magnesium-based housing/chassis). This technique may provide a thin, light, high-quality, thermally-beneficial housing/chassis that has a metallic or other premium-finish look while also maintaining the recyclability for the part and therefore helping to meet sustainability targets for the end-of-life recycling process for such products. As should be appreciated, while the disclosure below uses a laptop chassis/housing as an example of a part/component that may be finished with this process, the disclosed process may be applied to any type of part/component and used as housings in such electronic products as smartphones, medical devices, wearables, tablets, handhelds, and even as parts/components for other types of non-electronic products.

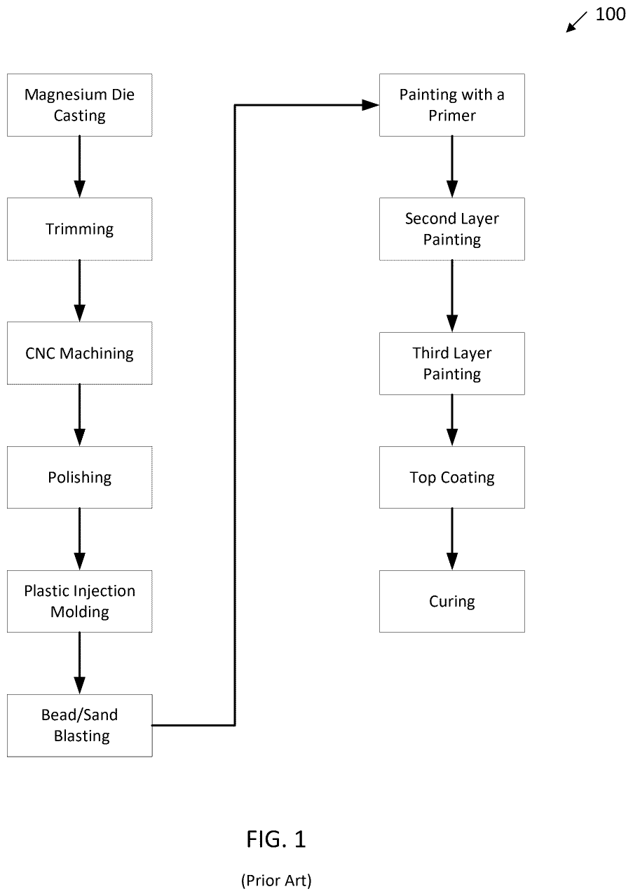

FIG. 1 shows a flow chart 100 for a conventional manufacturing process for producing a laptop housing formed from a conductive material such as magnesium, aluminum, other metals, or alloys thereof. The manufacturing process may start with raw materials (such as magnesium, aluminum, other metals, or alloys thereof) and end with a laptop chassis as it will be seen by the end-user. The process may include (1) die casting the raw material/metal; (2) trimming; (3) CNC (computer-numerical-control) machining; (4) polishing; (5) plastic injection molding; (6) sand/bead blasting; (7) painting with a primer; (8) painting with a second layer; (9) painting with a third layer; (10) top coating; and (11) curing. In the die casting step, the metal (typically a magnesium alloy or aluminum allow) is melted in a furnace and injected under high pressure into a mold (die) that forms the shape of the housing. Next, the excess material (flash) formed during the die casting process may be removed using trimming tools or machines. In the CNC machining step, tools may be used to mill, drill, or otherwise machine the housing to achieve the final dimensions and precision features like threads, holes, and grooves. In the polishing step, the machined housing is polished using abrasive materials to smooth out the surface and remove any machining marks.

For housings that require plastic components or overmolding (e.g., for decoration), plastic material is injected into a mold to form these parts, which are then bonded to or incorporated into the magnesium housing. Next, the housing may be blasted with sand/fine beads (often glass or ceramic) under high pressure to clean the surface and create a uniform matte finish for the housing. This cleans the surface of any residues and prepares it for painting by creating a slightly rough texture that helps paint adhere better. After the surface has been prepared, a primer layer may be applied to the housing, which acts as a base coat and helps subsequent paint layers adhere better. A second (and sometimes a third) coating may be applied to over the primer, where the second coat is often a color coat that provides the main visual appearance of the housing and the third paint layer is typically a clear coat, another color coat, or a specialty layer (e.g., metallic finish) to add depth to the color, enhance durability, and provide additional protection. A final top coat may be applied, which may be clear or colored coating, designed to provide additional protection, chemical resistance, and durability from environmental factors to ensure the longevity of the finish. Finally, a curing process, typically performed in an oven, is carried out in order to harden the paint layers and ensure they adhere properly to the magnesium substrate. Unfortunately, this process may not be able to provide a satisfactory, even finish on a metal chassis with plastic integrated into the housing (e.g., for supporting a wireless antenna) as is expected of premium systems.

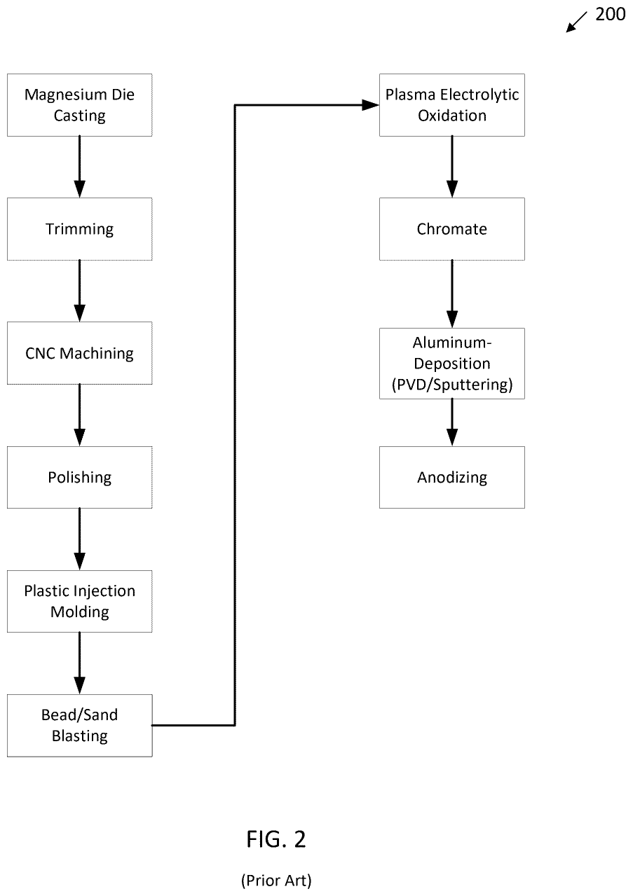

FIG. 2 shows a flow chart 200 for a modified manufacturing process for producing a laptop housing formed from a conductive material such as magnesium, where the painting magnesium has been replaced with a plastic (e.g., so that the antenna may be integrated into the housing) with a chromate conversion, followed by a thin layer of aluminum deposition through physical vapor deposition (PVD/sputtering) and then anodizing the aluminum layer. This process, however, tends to release gases under the aluminum layer during the PVD process (e.g., due to the chamber temperature), which eventually causes delamination of the aluminum layer. As a result, such a process may not reliably create a part that meets the cosmetic surface requirements/expectations, especially where the part is to be used in a premium product such as a premium laptop.

In contrast to the above-mentioned processes, the new finishing technique disclosed herein may be used to create a uniform and durable coating on a conductive surface (such as a magnesium-based surface) that has excellent corrosion resistance, provides an enhanced aesthetic appearance that is able to meet premium-level standards for appearance and seamless finishing, does not compromise the recyclability of the part, and may be used with plastics in order to support an attached/embedded wireless antenna. To accomplish this, the anodized finish may be replaced with cathodic electrodeposition (CED) plus a water-based primer coat plus a vapor/vacuum film transfer (VFT). The process involves the electrochemical deposition of a paint or other coating material onto a conductive surface (e.g., the part) using an electrical current.

In addition, graphics may be printed on the thin film (e.g., using one of or a mixture of several different types of printing processes to thin films), where the thin film may then be wrapped onto the chassis body (e.g., on outer surface as well as the in the core and cavity side). The wrapped film may then be attached/adhered to the surface of the chassis body using a VFT technique. As should be appreciated, the graphic printing onto the thin film may provide a way of producing an attractive part with unique colors, patterns, and textures, where even a gradient anodization finish may also be achievable with this process. As noted above, the process may also be considered a sustainable process because the water-based coating does not contaminate the part and therefore allows for its recycling and, overall, the process may reduce the carbon footprint as compared to the typical coating processes by around 20%. In addition, compared to a traditional solvent-based painting process, the cost of this process may be about 50% lower. In addition, a chassis made with this process may also receive high marks for reliability and be able to meet reliability testing typically expected of such parts.

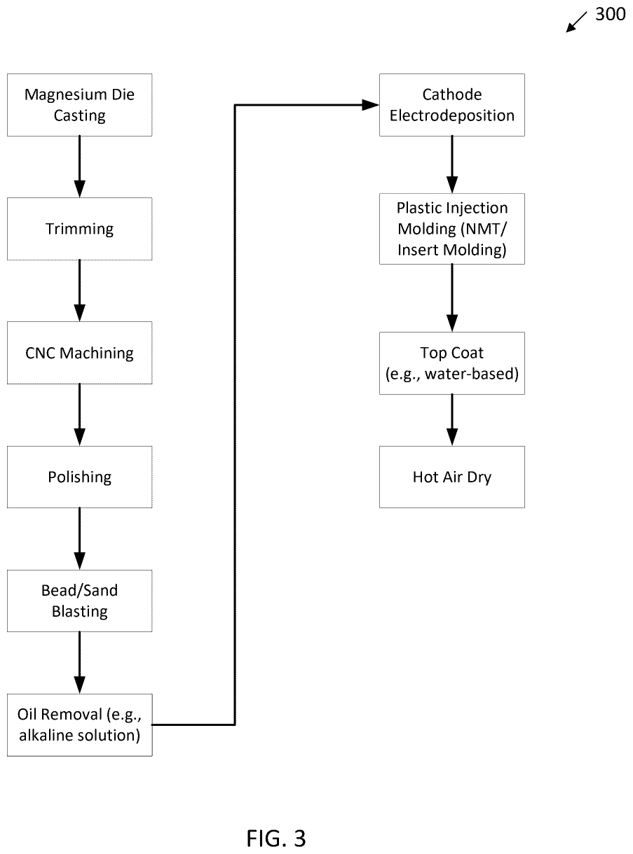

FIG. 3 shows a flow chart 300 for an example of the disclosed process for producing a metallic laptop housing (e.g., a fully metal part or a metal chassis body with antenna plastic). The process may include (1) die casting the raw material/metal; (2) trimming; (3) CNC machining; and (4) polishing, as with the conventional process described above with respect to FIG. 1. Next, the process may include a (5) sand/bead blasting process that scuffs the material to prepare the surface for cathodic electrodeposition. Next, an (6) oil removal step may be performed by treating the part with an alkaline solution (e.g., sodium-chloride with a pH value of approximately 5, to ensure the part itself is not dissolved during CED process). This step may be crucial for removing grease, oils, or other contaminants from the surface of the parts and for ensuring a clean surface for further processing and for better adhesion of subsequent films, coatings, etc. Once the surface has been prepared, (7) cathode electrodeposition may follow (e.g., approximately 6 minutes at 30° C.). In the cathodic electrodeposition process, also known as electrocoating or electrophoretic deposition, a paint or coating material may be applied to a conductive substrate using an electric field. Using a magnesium allow as an example substrate (e.g., formed in the die casting step), the part may be immersed in a bath containing a water-based paint. A direct current (DC) electric field may then be applied between the substrate (its conductive surface acting as the cathode) and an anode in the bath. This causes the paint particles to migrate and deposit onto the substrate, forming a uniform coating on the conductive surface. Next, (8) plastic injection molding, nano molding technology (NMT), or insert molding may be performed in order to allow for the direct molding of plastic onto metal components (e.g., in order to allow for attaching a wireless antenna to the housing). After plastic injection molding, the part may be (9) top coated with, for example, a polyurethane water-based paint. Next, a (10) hot air drying step (e.g., approximately 10 minutes at about 140° C.) may follow the top coating to arrive at the finished part.

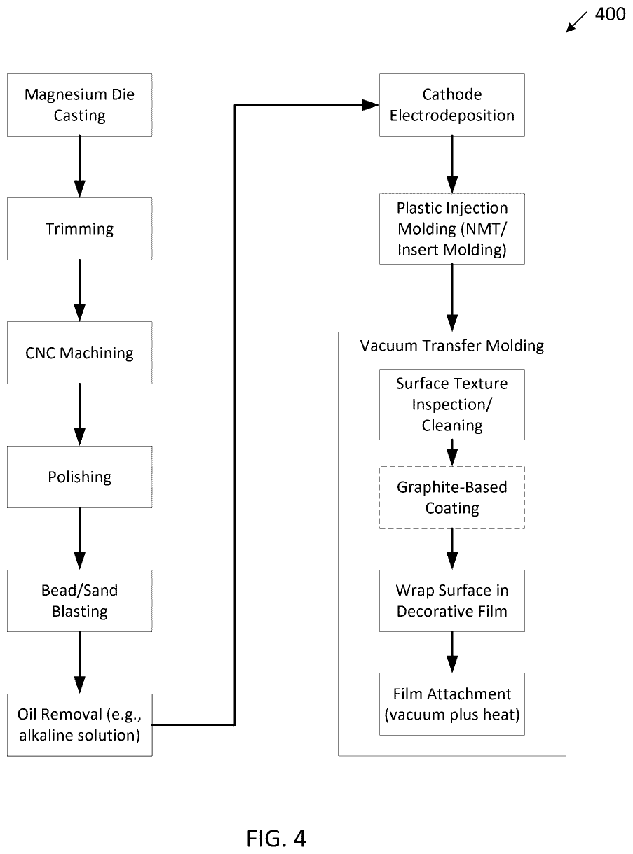

FIG. 4 shows a flow chart 400 for another example of the disclosed process for producing a metallic laptop housing (e.g., a metal part that allows for attaching a wireless antenna, such as a fifth generation (5G) antenna, to the part). The process may begin similar to that of FIG. 3, as described above, to include (1) die casting the raw material/metal; (2) trimming; (3) CNC machining; (4) polishing; (5) sand/bead blasting process; (6) oil removal by alkaline solution, (7) cathode electrodeposition; and (8) plastic injection molding. Next, rather than a top-coat, a vacuum transfer molding (VTM) process may be used to add a decorative thin film (e.g., a cosmetic layer or a thin film cosmetic layer). In this VTM process, a graphite-based layer (e.g., graphene) may be combined with the thin film (either deposited on the thin film itself or onto the outer surface of the part after pretreating the surface with an alkaline solution to clean off contaminates like oils, greases, etc.), and then the then film may be vacuumed (e.g., while applying heat to the part in a vacuum) and integrated onto the surface of the part. The thin film is designed to provide an attractive aesthetic and, if used with the graphite-based layer, a thermal benefit as well. It should be noted that the VTM process is different from in-mold decoration (IMD), which is typically performed during the molding process of a plastic part by transferring an ink into the mold to achieve the required finish/color from the plastic molding process. As should also be understood, although the graphite-based coating is shown as an optional feature of the VTM process, this may, in reality, occur before the VTM process, either as (1) a deposition step that deposits a graphite-based layer onto the surface of the part before the surface is wrapped with the decorative thin film or as (2) a manufacturing/coating process of the thin film itself that places a graphite-based layer onto (e.g. one side of) the thin film before it is wrapped around the part.

As should be understood, when a graphite-based layer is added between the surface of the part and outer thin film coating, this may provide a thermal benefit in terms of heat spreading, where the graphite-based layer acts as a heat exchanger between the housing and ambient, making the outer surface cooler to the touch. This may be particularly helpful when the part is used as a housing for electronic components that may generate significant heat within the housing. In such a case, the graphite-based layer, because of its presence on the outside of the housing, makes the outside surface of the housing cooler to the touch (e.g., to a user touching the outside of the housing).

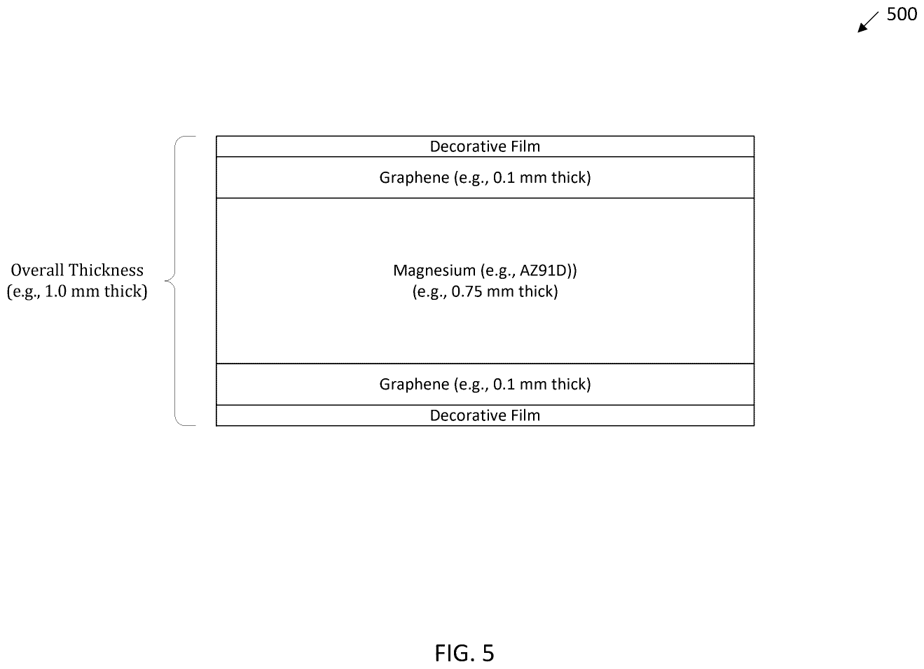

FIG. 5 shows an example stack-up 500 of a part (e.g., an A-cover, a C-cover, a D-cover, etc. of a laptop housing) that has been prepared using the thin-film process and including a graphite-based layer between the thin-film and the part's surface. The part may be formed from a conductive layer (e.g., a metallic core formed from a magnesium alloy such as AZ91D), as discussed above with the die casting step, that may be approximately 0.75 mm thick. A graphite-based layer (e.g., graphene) may be added between the conductive layer and the decorative/cosmetic thin film layer that has been attached to the conductive layer by VTM. The graphite-based layer may be approximately 0.1 mm thick, meaning that the overall thickness of the part may be approximately 1.0 mm. As should be appreciated, these layer thicknesses are merely exemplary, and any layer thicknesses (including non-uniform thicknesses) may be used.

In addition, while FIG. 5 shows that both sides of the part have been coated with a graphite-based layer and the decorative/cosmetic film, alternative layering is possible, where, for example, the graphite-based layer and/or the decorative film layer may be on either or both sides of the conductive layer/core. In addition, the graphite-based layer may be included on only a portion or multiple portions of the part (e.g., on the portions that may be the “hot spots” in which the part will be used, such as the portions of the housing that will be near a processor or near other devices that emit heat; on the portions that are not over an antenna so that the graphite-based layer does not adversely impact wireless transmissions/receptions of the antenna; etc.). As should be understood, the extent of the graphite-based layer may be selected based on thermal needs of the part, costs, wireless performance, etc.

As noted earlier, the improved process may provide (1) a sustainable painted magnesium chassis with 50% lower costs compared to traditional painted magnesium chassis and with 22% lower carbon (CO₂) emissions compared to a traditional painted chassis. For example, a conventional PVD plus anodizing process may involve steps of oil removal, plasma electrolytic deposition (PED), hot air drying, PVD, etching an anodizing, sealing, and a second hot air dry. Such a conventional PVD plus anodizing process may create 26.32 tons/year of CO₂ emissions and cost around 40 USD. In a conventional painting process, which may include steps of pre-treatment, hot air dry, priming, a second hot air dry, a top coat, a third hot air dry, etc., the conventional painting process may create 27.76 tons/year of CO₂ emissions and cost around 5 USD. In the disclosed process that uses CED plus a water-based paint, the processing may include oil removal, CED, hot air dry, a topcoat, a second hot air dry. Thus, the disclosed process may use water-based sustainable solvents so that the CO₂ may be estimated at 21.77 tons/year and cost around 2.5 USD, both of which are lower than the conventional methods.

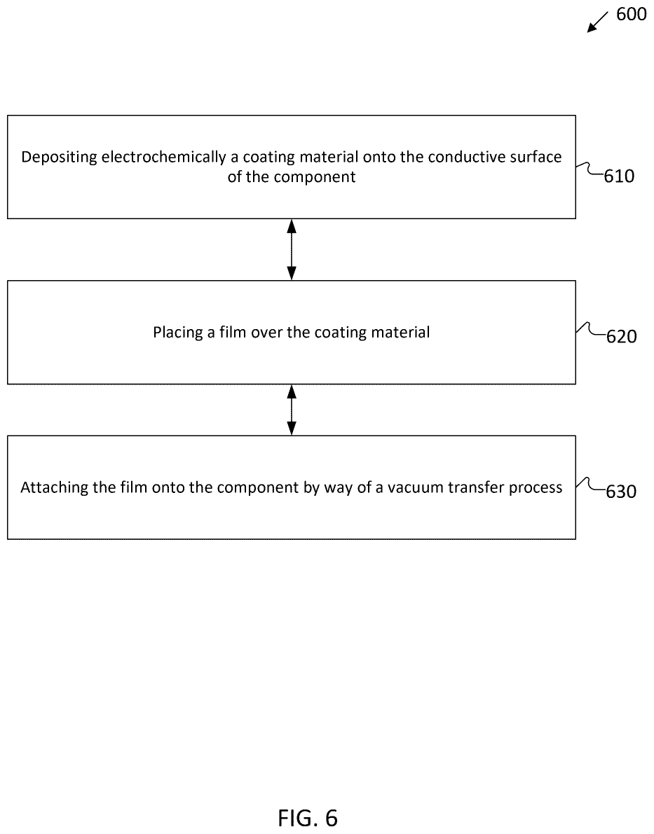

FIG. 6 shows a schematic flow diagram of a method 600 for producing a part with thin film coating. Method 600 may implement any of the features associated with the processing steps discussed above and/or with respect to FIGS. 1-5. Method 600 includes, in 610, depositing electrochemically a coating material onto the conductive surface of the component. Method 600 also includes, in 620, placing a film over the coating material. Method 600 also includes, in 630, attaching the film onto the component by way of a vacuum transfer process.

In the following, various examples are provided that may include one or more features of the coating process discussed above. It may be intended that aspects described in relation to the devices may apply also to the described method(s), and vice versa.

Example 1 is a method for finishing a component having a conductive surface, the method includes depositing electrochemically a coating material onto the conductive surface of the component. The method also includes placing a film over the coating material. The method also includes attaching the film onto the component by way of a vacuum transfer process.

Example 2 is the method of example 1, the method further including preprinting the film with a decorative pattern.

Example 3 is the method of example 2, wherein the decorative pattern includes a gradient anodization style finish.

Example 4 is the method of any one of examples 1 to 3, wherein the coating material includes a paint.

Example 5 is the method of example 4, wherein the paint includes a water-based primer.

Example 6 is the method of any one of examples 1 to 5, wherein one side of the film includes a graphite-based coating, wherein the placing of the film includes facing the graphite-based coating toward the coating material during the placing of the film.

Example 7 is the method of example 6, wherein the graphite-based coating includes a graphene sheet.

Example 8 is the method of any one of examples 1 to 7, the method further including applying, before the placing of the film, a graphite-based coating to the coating material or to a side of the film that faces the coating material during the placing of the film.

Example 9 is the method of any one of examples 1 to 8, wherein the conductive surface includes magnesium, a magnesium alloy (e.g., AZ91D), aluminum, an aluminum alloy, or another metal.

Example 10 is the method of any one of examples 1 to 9, the method further including die casting the conductive surface from a metallic raw material.

Example 11 is the method of any one of examples 1 to 10, wherein the component is a housing for an electronic device.

Example 12 is the method of example 11, wherein the electronic device is a laptop, wherein the housing includes a laptop cover with an embedded wireless antenna for wireless communications of the laptop.

Example 13 is the method of any one of examples 1 to 12, wherein the depositing the coating electrochemically includes immersing the conductive surface in a bath containing the coating material and applying an electric current between the coating material and the conductive surface.

Example 14 is the method of example 13, wherein the electric current is a direct electric current (DC).

Example 15 is the method of any one of examples 1 to 14, the method further including pretreating, before the depositing, the conductive surface of the component with an alkaline solution.

Example 16 is the method of example 15, wherein the alkaline solution is a sodium chloride (NaCl) solution with a pH value of approximately 5.

Example 17 is the method of any one of examples 1 to 16, wherein the vacuum transfer process includes applying heat to the component in a vacuum.

Example 18 is the method of any one of examples 1 to 17, wherein the conductive surface includes an injection molded plastic integrated with metal.

Example 19 is the method of any one of examples 1 to 18, wherein the component includes an antenna that is electrically isolated from the conductive surface.

Example 20 is a layer stack of materials for housing electronic components, the material layer stack including a conductive layer; a graphite-based layer stacked on and attached to one side of the conductive layer; a thin film cosmetic layer stacked on and attached to the first graphite-based layer.

Example 21 is the layer stack of materials of example 20, wherein the thin film cosmetic layer is about 0.25 mm thick.

Example 22 is the layer stack of materials of any one of examples 20 to 21 further including a second graphite-based layer stacked on and attached to the other side of the conductive layer opposite to the one side.

Example 23 is the layer stack of materials of example 20 further including a second thin film cosmetic layer stacked on attached to the second graphite-based layer.

Example 24 is the layer stack of materials of any one of examples 20 to 23, wherein the graphite-based layer includes graphene.

Example 25 is the layer stack of materials of any one of examples 20 to 24, wherein the conductive layer includes magnesium, a magnesium alloy (e.g., AZ91D), aluminum, an aluminum alloy, or another metal.

Example 26 is the layer stack of materials of any one of examples 20 to 25, wherein the layer stack of materials includes an A-cover, a C-cover or a D-cover of a laptop.

Example 27 is a device for finishing a component having a conductive surface, the device includes a means for depositing electrochemically a coating material onto the conductive surface of the component. The device also includes a means for placing a film over the coating material. The device also includes a means for attaching the film onto the component by way of a vacuum transfer process.

Example 28 is the device of example 27, the device further including a means for preprinting the film with a decorative pattern.

Example 29 is the device of example 28, wherein the decorative pattern includes a gradient anodization style finish.

Example 30 is the device of any one of examples 27 to 29, wherein the coating material includes a paint.

Example 31 is the device of example 30, wherein the paint includes a water-based primer.

Example 32 is the device of any one of examples 27 to 31, wherein one side of the film includes a graphite-based coating, wherein the means for placing the film includes a means for facing the graphite-based coating toward the coating material during the placing of the film.

Example 33 is the device of example 32, wherein the graphite-based coating includes a graphene sheet.

Example 34 is the device of any one of examples 27 to 33, the device further including a means for applying, before the placing of the film, a graphite-based coating to the coating material or to a side of the film that faces the coating material during the placing of the film.

Example 35 is the device of any one of examples 27 to 34, wherein the conductive surface includes magnesium, a magnesium alloy (e.g., AZ91D), aluminum, an aluminum alloy, or another metal.

Example 36 is the device of any one of examples 27 to 35, the device further including a means for die casting the conductive surface from a metallic raw material.

Example 37 is the device of any one of examples 27 to 36, wherein the component is a housing for an electronic device.

Example 38 is the device of example 37, wherein the electronic device is a laptop, wherein the housing includes a laptop cover with an embedded wireless antenna for wireless communications of the laptop.

Example 39 is the device of any one of examples 27 to 38, wherein the means for depositing the coating electrochemically includes a means for immersing the conductive surface in a bath containing the coating material and applying an electric current between the coating material and the conductive surface.

Example 40 is the device of example 39, wherein the electric current is a direct electric current (DC).

Example 41 is the device of any one of examples 27 to 40, the device further including a means for pretreating, before the depositing, the conductive surface of the component with an alkaline solution.

Example 42 is the device of example 41, wherein the alkaline solution is a sodium chloride (NaCl) solution with a pH value of approximately 5.

Example 43 is the device of any one of examples 27 to 42, wherein the vacuum transfer process includes a means for applying heat to the component in a vacuum.

Example 44 is the device of any one of examples 27 to 43, wherein the conductive surface includes an injection molded plastic integrated with metal.

Example 45 is the device of any one of examples 27 to 44, wherein the component includes an antenna that is electrically isolated from the conductive surface.

Example 46 is a process for making a chassis, the process including: forming a chassis body; depositing via electrochemical deposition a coating material onto a conductive surface of the chassis body; and layering via a vacuum transfer process a thin film over the coating material, wherein the vacuum transfer process comprises wrapping the conductive surface with the thin film and attaching the thin film onto the chassis body by vacuum transfer.

Example 47 is the process of example 46, wherein the process further includes forming a decorative pattern on the thin film by preprinting onto the thin film.

Example 48 is the process of example 47, wherein the decorative pattern includes a gradient anodization style finish.

Example 49 is the process of any one of examples 46 to 48, wherein the coating material includes a paint.

Example 50 is the process of example 49, wherein the paint includes a water-based primer.

Example 51 is the process of any one of examples 46 to 50, wherein one side of the thin film includes a graphite-based coating, and wherein the layering the thin film over the coating material includes layering the thin film over the coating material with the graphite-based coating facing the coating material.

Example 52 is the process of example 51, wherein the graphite-based coating includes a graphene sheet.

Example 53 is the process of any one of examples 46 to 52, the process further including coating the thin film with the graphite-based coating before the wrapping the conductive surface with the thin film.

Example 54 is the process of any one of examples 46 to 53, the process further comprising coating the conductive surface with the graphite-based coating before the wrapping the conductive surface with the thin film.

Example 55 is the process of any one of examples 46 to 54, wherein the conductive surface includes magnesium, a magnesium alloy, aluminum, an aluminum alloy, or another metal.

Example 56 is the process of any one of examples 46 to 55, wherein the forming the chassis body includes die casting the chassis body from a metallic raw material.

Example 57 is the process of any one of examples 46 to 56, wherein the chassis is a housing for an electronic device.

Example 58 is the process of example 57, wherein the electronic device is a laptop, wherein the housing includes a laptop cover with an embedded wireless antenna for wireless communications of the laptop.

Example 59 is the process of any one of examples 46 to 58, wherein the depositing the coating material onto the conductive surface of the chassis body by electrochemical deposition includes immersing the conductive surface in a bath containing the coating material and applying an electric current between the coating material and the conductive surface.

Example 60 is the process of example 59, wherein the electric current is a direct electric current.

Example 61 is the process of any one of examples 46 to 60, wherein before the depositing the coating material, the process further includes pretreating the conductive surface of the chassis body with an alkaline solution.

Example 62 is the process of example 61, wherein the alkaline solution is a sodium chloride solution with a pH value of approximately 5.

Example 63 is the process of any one of examples 46 to 62, wherein the vacuum transfer process includes applying heat to the chassis body in a vacuum.

Example 64 is the process of any one of examples 46 to 63, wherein the process further includes forming the conductive surface by injection molding plastic that is integrated with metal.

Example 65 is the process of any one of examples 46 to 64, wherein the chassis body includes an antenna that is electrically isolated from the conductive surface.

While the disclosure has been particularly shown and described with reference to specific aspects, it should be understood by those skilled in the art that various changes in form and detail may be made therein without departing from the spirit and scope of the disclosure as defined by the appended claims. The scope of the disclosure is thus indicated by the appended claims and all changes, which come within the meaning and range of equivalency of the claims, are therefore intended to be embraced.

Claimed is:

1. A method comprising:
depositing electrochemically a coating material onto a conductive surface of a component;
placing a film over the coating material; and
attaching the film onto the component by way of a vacuum transfer process.

2. The method of claim 1, the method further comprising preprinting the film with a decorative pattern.

3. The method of claim 2, wherein the decorative pattern comprises a gradient anodization style finish.

4. The method of claim 1, wherein the coating material comprises a paint comprising a water-based primer.

5. The method of claim 1, wherein one side of the film comprises a graphite-based coating, wherein the placing of the film comprises facing the graphite-based coating toward the coating material during the placing of the film.

6. The method of claim 5, wherein the graphite-based coating comprises a graphene sheet.

7. The method of claim 1, the method further comprising applying, before the placing of the film, a graphite-based coating to the coating material or to a side of the film that faces the coating material during the placing of the film.

8. The method of claim 1, wherein the conductive surface comprises magnesium, a magnesium alloy, aluminum, an aluminum alloy, or another metal.

9. The method of claim 1, the method further comprising die-casting the conductive surface from a metallic raw material.

10. The method of claim 1, wherein the component is a housing for a laptop, wherein the housing comprises a laptop cover with an embedded wireless antenna for wireless communications of the laptop, wherein the component comprises the embedded wireless antenna, wherein the embedded wireless antenna is electrically isolated from the conductive surface.

11. The method of claim 1, wherein the depositing the coating material electrochemically comprises immersing the conductive surface in a bath containing the coating material and applying an electric current between the coating material and the conductive surface.

12. The method of claim 11, wherein the electric current is a direct electric current.

13. The method of claim 1, the method further comprising pretreating, before the depositing, the conductive surface of the component with a sodium chloride solution with a pH value of approximately 5.

14. The method of claim 1, wherein the vacuum transfer process comprises applying heat to the component in a vacuum, wherein the conductive surface comprises an injection molded plastic integrated with metal.

15. A layer stack of materials for housing electronic components, the layer stack comprising:
a conductive layer;
a graphite-based layer stacked on and attached to one side of the conductive layer; and
a thin film cosmetic layer stacked on and attached to the graphite-based layer.

16. The layer stack of materials of claim 15, wherein the thin film cosmetic layer is about 0.25 mm thick.

17. The layer stack of materials of claim 15, the layer stack further comprising a second graphite-based layer stacked on and attached to another side of the conductive layer opposite to the one side.

18. A process for making a chassis, the process comprising:
forming a chassis body;
depositing via electrochemical deposition a coating material onto a conductive surface of the chassis body; and
layering via a vacuum transfer process a thin film over the coating material, wherein the vacuum transfer process comprises wrapping the conductive surface with the thin film and attaching the thin film onto the chassis body by vacuum transfer.

19. The process of claim 18, the process further comprising: coating the thin film with a graphite-based coating before the wrapping the conductive surface with the thin film; or coating the conductive surface with the graphite-based coating before the wrapping the conductive surface with the thin film.

20. The process of claim 18, the process further comprising pretreating the coating material, after the depositing and before the vacuum transfer process, with an alkaline solution.
